(19) United States
(12) Patent Application Publication
(10) Pub. No.: US 2010/0233620 A1
(43) Pub. Date: Sep. 16, 2010

(54) Copolymer and photoresist composition including the same

(76) Inventors: Sang-Jun Choi, Seoul (KR); Youn-Jin Cho, Anyang-city (KR); Seung-Wook Shin, Anyang-city (KR)

Correspondence Address: LEE & MORSE, P.C., 3141 FAIRVIEW PARK DRIVE, SUITE 500, FALLS CHURCH, VA, 22042, US

(21) Appl. No.: 12/801,145

(22) Filed: May 25, 2010

Related U.S. Application Data
(63) Continuation of application No. PCT/KR2007/007040, filed on Dec. 31, 2007.

(30) Foreign Application Priority Data
Nov. 26, 2007 (KR) 10-2007-0121123

(51) Int. Cl. G03F 7/004; C08F 134/02

(52) U.S. Cl. 430/270.1; 526/270; 526/266

(57) ABSTRACT

A resist copolymer includes a repeating unit having the following Chemical Formula 1, a repeating unit having the following Chemical Formula 2, and a repeating unit having the following Chemical Formula 3:

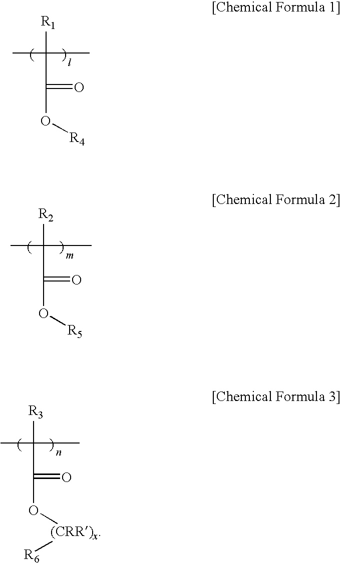

### CROSS-REFERENCE TO RELATED APPLICATION

This application is a continuation of pending International Application No. PCT/KR2007/007040, entitled “Novel Copolymers and Photoresist Composition Including the Same,” which was filed on Dec. 31, 2007, the entire contents of which are hereby incorporated by reference.

### BACKGROUND

1. Field

Embodiments relate to a copolymer and a resist composition including the same.

2. Description of the Related Art

Complications of a semiconductor manufacturing process and integration of semiconductors have increasingly required forming a fine pattern. For example, a semiconductor device with a capacity of more than 16 gigabytes may have a pattern size of less than 70 nm according to a design rule.

For lithography, a photoresist material using a shorter wavelength, such as an ArF excimer laser of 193 nm, is preferred to one using a longer wavelength, such as a KrF excimer laser of 248 nm. An ArF resist may include an acryl-based or methacryl-based polymer. However, these polymers may exhibit poor dry etching resistance, i.e., the etch selectivity may be low, causing difficulties in performing a dry etching process using plasma gas during the semiconductor device manufacturing process.

### SUMMARY

It is a feature of an embodiment to provide a copolymer and a resist composition including the same that are inexpensive to manufacture and exhibit sufficient resistance for dry etching.

It is another feature of an embodiment to provide a copolymer and a resist composition including the same that exhibit excellent adhesion to an underlayer.

It is another feature of an embodiment to provide a copolymer and a resist composition including the same that can be used under an exposure light source emitting light in an ultrashort wavelength region such as EUV (13.5 nm) as well as the 193 nm ArF region.

At least one of the above and other features and advantages may be realized by providing a resist copolymer, including a repeating unit having the following Chemical Formula 1, a repeating unit having the following Chemical Formula 2, and a repeating unit having the following Chemical Formula 3:

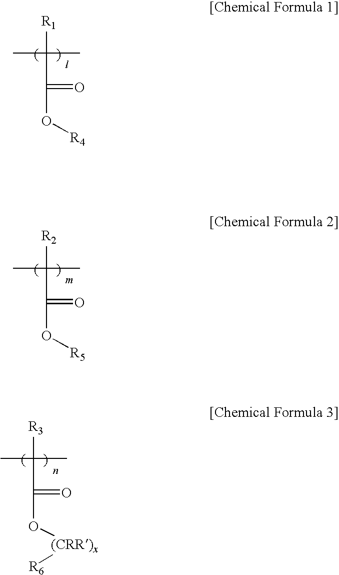

wherein, in the above Chemical Formulae,

R₁ to R₃ are independently hydrogen or a methyl,

R₄ is a C4 to C20 acid-labile group,

R₅ is a lactone-derived group,

R₆ is a tertiary alcohol cycloalkyl,

x is an integer ranging from 1 to 6,

R and R′ are independently hydrogen or an alkyl, and

l, m, and n are mole ratios of the repeating units, l/(l+m+n) being about 0.1 to about 0.5, m/(l+m+n) being about 0.3 to about 0.5, and n/(l+m+n) being about 0.1 to about 0.4.

The copolymer may have a weight average molecular weight (Mw) of about 3,000 to about 30,000.

The acid-labile group may be norbornyl, isobornyl, cyclodecanyl, adamantyl, norbornyl having a lower alkyl substituent, isobornyl having a lower alkyl substituent, cyclodecanyl having a lower alkyl substituent, adamantyl having a lower alkyl substituent, alkoxycarbonyl, alkoxycarbonylalkyl, amyloxycarbonyl, amyloxycarbonylalkyl, 2-tetrahydropyranyloxycarbonylalkyl, 2-tetrahydrofuranyloxycarbonylalkyl, a tertiary alkyl, or an acetal.

The acid-labile group may be 2-methyl-2-norbornyl, 2-ethyl-2-norbornyl, 2-methyl-2-isobornyl, 2-ethyl-2-isobornyl, 8-methyl-8-tricyclodecanyl, 8-ethyl-8-tricyclodecanyl, 2-methyl-2-adamantyl, 2-ethyl-2-adamantyl, 2-propyl-2-adamantyl, t-butoxycarbonyl, t-butoxycarbonylmethyl, t-amyloxycarbonyl, t-amyloxycarbonylmethyl, 1-ethoxyethoxycarbonylmethyl, 2-tetrahydropyranyloxycarbonylalkyl, 2-tetrahydrofuranyloxycarbonylalkyl, t-butyl, triethylcarbyl, 1-methyl cyclohexyl, 1-ethylcyclopentyl, t-amyl, or an acetal.

The lactone-derived group may be represented by the following Chemical Formula 4 or 5:

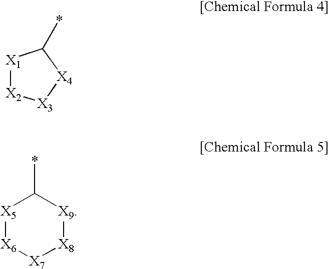

In the above Chemical Formula 4, at least two of X₁ to X₄ may be independently CO and O, and the remaining may be CR″ (where R″ is hydrogen, an alkyl, or an alkylene forming a fused ring with the five-member ring), and, in the above Chemical Formula 5, at least two of X₅ to X₉ may be independently CO and O, and the remaining may be CR″, where R″ is hydrogen, an alkyl, or an alkylene forming a fused ring with the five-member ring, or all X₅ to X₉ may be CR′″, where R′″ is hydrogen, an alkyl, or an ester-containing alkylene forming a fused ring with the six-member ring, and at least two of R′″ are linked with each other to form a lactone ring.

The lactone-derived group may be butyrolactonyl, valerolactonyl, 1,3-cyclohexanecarbolactonyl, 2,6-norbornanecarbolacton-5-yl, or 7-oxa-2,6-norbornanecarbolacton-5-yl.

The tertiary alcohol cycloalkyl may be a tertiary alcohol norbornyl, a tertiary alcohol adamantyl, a tertiary alcohol cyclopentanyl, or a tertiary alcohol cyclohexanyl.

At least one of the above and other features and advantages may also be realized by providing a resist composition, including a copolymer including a repeating unit having the following Chemical Formula 1, a repeating unit having the following Chemical Formula 2, and a repeating unit having the following Chemical Formula 3,

a photoacid generator, and

a solvent,

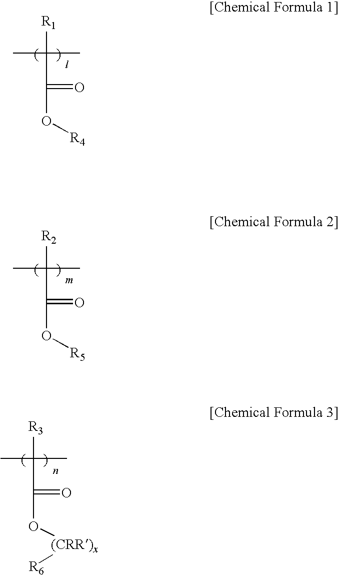

wherein, in the above Chemical Formulae,

R₁ to R₃ are independently hydrogen or methyl,

R₄ is a C4 to C20 acid-labile group,

R₅ is a lactone-derived group,

R₆ is a tertiary alcohol cycloalkyl,

x is an integer ranging from 1 to 6,

R and R′ are independently hydrogen or an alkyl, and

l, m, and n are mole ratios of the repeating units, l/(l+m+n) being about 0.1 to about 0.5, m/(l+m+n) being about 0.3 to about 0.5, and n/(l+m+n) being about 0.1 to about 0.4.

The copolymer may have a weight average molecular weight (Mw) of about 3,000 to about 30,000.

The acid-labile group may be norbornyl, isobornyl, cyclodecanyl, adamantyl, norbornyl having a lower alkyl substituent, isobornyl having a lower alkyl substituent, cyclodecanyl having a lower alkyl substituent, adamantyl having a lower alkyl substituent, alkoxycarbonyl, alkoxycarbonylalkyl, amyloxycarbonyl, amyloxycarbonylalkyl, 2-tetrahydropyranyloxycarbonylalkyl, 2-tetrahydrofuranyloxycarbonylalkyl, a tertiary alkyl, or an acetal.

The acid-labile group may be 2-methyl-2-norbornyl, 2-ethyl-2-norbornyl, 2-methyl-2-isobornyl, 2-ethyl-2-isobornyl, 8-methyl-8-tricyclodecanyl, 8-ethyl-8-tricyclodecanyl, 2-methyl-2-adamantyl, 2-ethyl-2-adamantyl, 2-propyl-2-adamantyl, t-butoxycarbonyl, t-butoxycarbonylmethyl, t-amyloxycarbonyl, t-amyloxycarbonylmethyl, 1-ethoxyethoxycarbonylmethyl, 2-tetrahydropyranyloxycarbonylalkyl, 2-tetrahydrofuranyloxycarbonylalkyl, t-butyl, triethylcarbyl, 1-methyl cyclohexyl, 1-ethylcyclopentyl, t-amyl, or an acetal.

The lactone-derived group may be represented by the following Chemical Formula 4 or 5:

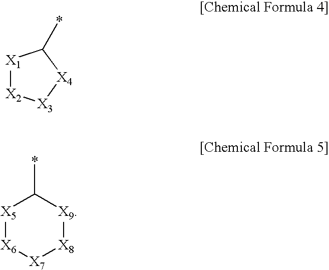

In the above Chemical Formula 4, at least two of X₁ to X₄ may be independently CO and O, and the remaining may be CR″, where R″ is hydrogen, an alkyl, or an alkylene forming a fused ring with the five-member ring, and, in the above Chemical Formula 5, at least two of X₅ to X₉ may be independently CO and O, and the remaining may be CR″, where R″ is hydrogen, an alkyl, or an alkylene forming a fused ring with the five-member ring, or all of X₅ to X₉ may be CR′″, where R′″ is hydrogen, an alkyl, or an ester-containing alkylene forming a fused ring with the six-member ring, and at least two of R′″ are linked each other to form a lactone ring.

The lactone-derived group may be butyrolactonyl, valerolactonyl, 1,3-cyclohexanecarbolactonyl, 2,6-norbornanecarbolacton-5-yl, or 7-oxa-2,6-norbornanecarbolacton-5-yl.

The tertiary alcohol cycloalkyl may be a tertiary alcohol norbornyl, a tertiary alcohol adamantyl, a tertiary alcohol cyclopentanyl, or a tertiary alcohol cyclohexanyl.

The photoacid generator may be included in an amount of about 1 to about 15 parts by weight based on 100 parts by weight of the copolymer.

The photoacid generator may include triarylsulfonium salts, diaryliodonium salts, sulfonates, or a mixture thereof.

The photoacid generator may include triarylsulfonium triflate, diaryliodonium triflate, triarylsulfonium nonaflate, diaryliodonium nonaflate, succinimidyl triflate, 2,6-dinitrobenzyl sulfonate, or a mixture thereof.

The composition may further include about 0.1 to about 1.0 parts by weight of an organic base based on 100 parts by weight of the copolymer.

The organic base may include triethylamine, triisobutylamine, trioctylamine, triisodecylamine, triethanolamine, or a mixture thereof.

### BRIEF DESCRIPTION OF THE DRAWINGS

The above and other features and advantages will become more apparent to those of skill in the art by describing in detail example embodiments with reference to the attached drawings, in which:

FIG. 1 illustrates a FT-IR spectrum of a copolymer according to Example 1-1.

FIG. 2 illustrates a photograph showing a pattern formed using the resist composition including the copolymer according to Example 1-1.

### DETAILED DESCRIPTION

Korean Patent Application No. 10-2007-0121123, filed on Nov. 26, 2007, in the Korean Intellectual Property Office, and entitled: “Novel Copolymers and Photoresist Composition Including the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. In the drawing figures, the dimensions of layers and regions may be exaggerated for clarity of illustration. Like reference numerals refer to like elements throughout.

A photosensitive polymer material according to an embodiment may include a polymer having a tertiary alcohol alicyclic moiety, which may provide the polymer with both etching resistance of a resist and adhesion to an underlayer. The photosensitive polymer may have a basic compound structure of an alicyclic group having etching resistance to a dry etching and a tertiary alcohol group that is capable of improving adhesion to the underlayer. A resist composition using the photosensitive polymer may remarkably improve a dry etching characteristic and adhesion to an underlayer compared to conventional resist materials for ArF, and may show a strong characteristic for preventing a pattern collapse phenomenon while manufacturing a semiconductor device. The photosensitive polymer may be useful for providing the next generation semiconductor device.

A resist polymer according to an example embodiment includes repeating units of the following Chemical Formulae 1 to 3.

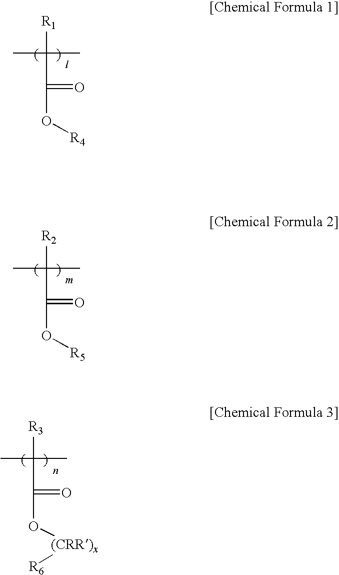

In the above Chemical Formulae, R₁ to R₃ may be independently hydrogen or methyl.

In the above Chemical Formulae, R₄ may be a C4 to C20 acid-labile group capable of being decomposed under an acid catalyst. R₄ is preferably norbornyl, isobornyl, cyclodecanyl, adamantyl, norbornyl having a lower alkyl substituent, isobornyl having a lower alkyl substituent, cyclodecanyl having a lower alkyl substituent, adamantyl having a lower alkyl substituent, alkoxycarbonyl, alkoxycarbonylalkyl, amyloxycarbonyl, amyloxycarbonylalkyl, 2-tetrahydropyranyloxycarbonylalkyl, 2-tetrahydrofuranyloxycarbonylalkyl, a tertiary alkyl, or an acetal, and is more preferably 2-methyl-2-norbornyl, 2-ethyl-2-norbornyl, 2-methyl-2-isobornyl, 2-ethyl-2-isobornyl, 8-methyl-8-tricyclodecanyl, 8-ethyl-8-tricyclodecanyl, 2-methyl-2-adamantyl, 2-ethyl-2-adamantyl, 2-propyl-2-adamantyl, t-butoxycarbonyl, t-butoxycarbonylmethyl, t-amyloxycarbonyl, t-amyloxycarbonylmethyl, 1-ethoxyethoxycarbonylmethyl, 2-tetrahydropyranyloxycarbonylalkyl, 2-tetrahydrofuranyloxycarbonylalkyl, alkoxycarbonylalkyl, amyloxycarbonyl, amyloxycarbonylalkyl, 2-tetrahydropyranyloxycarbonylalkyl, 2-tetrahydrofuranyloxycarbonylalkyl, t-butyl, triethylcarbyl, 1-methyl cyclohexyl, 1-ethylcyclopentyl, t-amyl, or an acetal.

In the above Chemical Formulae, R₅ may be a lactone-derived group of Chemical Formulae 4 or 5, below. Preferably, R₅ is butyrolactonyl, valerolactonyl, 1,3-cyclohexanecarbolactonyl, 2,6-norbornanecarbolacton-5-yl, or 7-oxa-2,6-norbornanecarbolacton-5-yl.

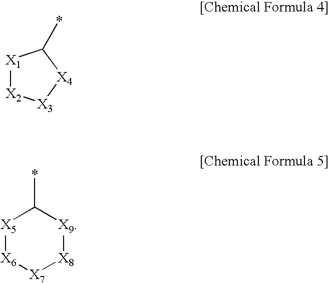

In the above Formula 4, at least two of X₁ to X₄ may be independently CO and O, and the remaining group except CO and O may be CR″ (where R″ is hydrogen, an alkyl, or an alkylene forming a fused ring with the five-member ring).

In the above Formula 5, at least two of X₅ to X₉ may be independently CO and O, and the remaining group except CO and O may be CR″ (where R″ is hydrogen, an alkyl, or an alkylene forming a fused ring with the five-member ring), or, in another embodiment, all of X₅ to X₉ may be CR′″ (where R′″ is hydrogen, an alkyl, or an ester-containing alkylene forming a fused ring with the six-member ring) and at least two R′″ may be linked to each other to form a lactone ring.

According to an example embodiment, R₆ may be a tertiary alcohol cycloalkyl. R₆ may be a substituted or unsubstituted tertiary alcohol norbornyl, a substituted or unsubstituted tertiary alcohol adamantyl, a substituted or unsubstituted tertiary alcohol cyclopentanyl, or a substituted or unsubstituted tertiary alcohol cyclohexanyl. Preferably, R₆ is a tertiary alcohol alicyclic group such as a tertiary alcohol norbornyl or a tertiary alcohol adamantyl. The substituted norbornyl, adamantyl, cyclopentanyl, and cyclohexanyl may have a tertiary alcohol at a position bound with CRR′, and remaining lower alkyl substituents in the above Formula 3. Specific examples of the tertiary alcohol alicyclic group include 2-hydroxy-2-norbornyl and 2-hydroxy-2-adamantyl. R₆ may be obtained by a Grignard reaction.

According to an example embodiment, x may be an integer ranging from 1 to about 6, and R and R′ may be independently hydrogen or an alkyl. R and R′ are preferably hydrogen or a C1 to C4 lower alkyl.

In Chemical Formulae 1 to 3, l, m, and n are mole ratios of the repeating units. According to an example embodiment, l/(l+m+n) may be about 0.1 to about 0.5, m/(l+m+n) may be about 0.3 to 0.5, and n/(l+m+n) may be about 0.1 to 0.4.

As used herein, when specific definition is not otherwise provided, “an alkyl” may refer to a C1 to C20 alkyl, preferably a C1 to C12 alkyl, “a lower alkyl” may refer to a C1 to C4 alkyl, “an alkylene” may refer to a C1 to C20 alkylene, preferably a C1 to C12 alkylene, “an alkoxy” may refer to a C1 to C20 alkoxy, preferably a C1 to C12 alkoxy, “an alkenyl” may refer to a C2 to C20 alkenyl, preferably a C2 to C12 alkenyl, “an aryl” may refer to a C6 to C20 aryl, preferably a C6 to C12 aryl, “a heteroaryl” may refer to a C2 to C20 heteroaryl, preferably a C2 to C12 heteroaryl, “a cycloalkyl” may refer to a C3 to C20 cycloalkyl, preferably a C5 to C15 cycloalkyl, and “a heterocycloalkyl” may refer to a C2 to C20 heterocycloalkyl, preferably a C3 to C10 heterocycloalkyl. In the present specification, “heteroaryl” and “heterocycloalkyl” may refer to one including 1 to 3 heteroatoms selected from the group consisting of nitrogen (N), oxygen (O), sulfur (S), and phosphorus (P), and remaining carbon.

As used herein, when specific definition is not otherwise provided, the term “substituted” may refer to one substituted with at least a substituent selected from the group consisting of a hydroxy, a halogen, a substituted or unsubstituted linear or branched alkyl, a substituted or unsubstituted cycloalkyl, a substituted or unsubstituted heterocycloalkyl, a substituted or unsubstituted alkoxy, a substituted or unsubstituted aryl, a substituted or unsubstituted heteroaryl, and a substituted or unsubstituted alkenyl.

According to an example embodiment, the photosensitive copolymer having a repeating unit of Chemical Formulae 1 to 3 may have a weight average molecular weight (Mw) of about 3,000 to about 30,000. According to an example embodiment, the photosensitive copolymer may have a degree of dispersion (Mw/Mn) of about 1.5 to about 2.5, which may provide excellent etching resistance and resolution.

The photosensitive copolymer having a repeating unit of Chemical Formulae 1 to 3 may be obtained from alicyclic monomers having novel functionality, and may have advantages of providing a resist composition having both excellent adhesion to an underlayer and excellent dry etching resistance. These monomers include an alicyclic compound having a form of a tertiary alcohol, which may be synthesized through a Grignard reaction and may improve both adhesion to the layer and etching resistance. Accordingly, the photosensitive copolymer material using the monomers may overcome the drawbacks of conventional ArF resist materials with respect to dry etching resistance, and may be used to satisfy requirements for an etching mask in a semiconductor device that requires a higher resolution. When a resist composition according to an embodiment is applied in a photolithography process, it may provide excellent lithography performance.

The monomer having a tertiary alcohol alicyclic substituent for the photosensitive composition according to an embodiment may be prepared in accordance with the following reaction.

A methacrylate or acrylate compound having a form of an alkyl halide may be reacted with a magnesium metal to provide a Grignard solution, and then alicyclic ketone compounds may be added thereto and reacted therewith.

The ketone compounds used for the Grignard reaction may include, e.g., general alicyclic compounds. According to an example embodiment, the ketone compounds include cyclopentanone, cyclohexanone, 2-norbornanone, 2-adamantanone, and so on.

A method of preparing the photosensitive copolymer according to an embodiment will now be described.

The synthesized monomer having a tertiary alcohol group, a monomer having an acid degradable group, and monomers having a lactone group may be dissolved in a polymerization solvent (e.g., tetrahydrofuran or dioxane) together with about 2 to about 10 mol % (based on the total ratio of monomer components) of a polymerization catalyst (e.g., azobisisobutyronitrile (AIBN) or V601 (trade name, manufactured by Wako). The amount of solvent may be about 2 to about 4 times more than the total weight of monomer. Then, the monomers may be polymerized at a temperature of about 60 to about 80° C. for about 4 to about 8 hours. After the polymerization is completed, the reactant may be slowly precipitated in an excess amount of precipitation solvent (e.g., n-hexane, diethyl ether, isopropyl alcohol, etc.), and the precipitates may be filtered and dried in a vacuum oven at about 40° C. for about 24 hours to provide a polymer.

Another embodiment provides a resist composition that may have excellent etching resistance, the resist composition including a polymer having a repeating unit represented by Chemical Formulae 1 to 3, a photoacid generator (PAG), and a solvent.

The PAG may include, e.g., triarylsulfonium salts, diaryliodonium salts, sulfonates, or a mixture thereof. According to an example embodiment, the PAG may include triarylsulfonium triflate, diaryliodonium triflate, triarylsulfonium nonaflate, diaryliodonium nonaflate, succinimidyl triflate, 2,6-dinitrobenzyl sulfonate, or a mixture thereof.

The photoacid generator may be added at about 1 to about 15 parts by weight based on 100 parts by weight of the copolymer. Maintaining the amount of the PAG at about 1 part by weight or more may help avoid problems where the exposure amount is excessive with respect to the resist composition. Maintaining the amount of the PAG at about 15 parts by weight or less may help avoid decreases in the transmission of the resist composition.

The solvent may include PGMEA (propylene glycol monomethyl ether acetate), PGME (propylene glycol methyl ether), ethyl lactate (EL), cyclohexanone, 2-heptanone, mixtures thereof, and so on. The solvent may be added at the balance amount of the composition. In an embodiment, the solvent may be added at about 80 wt % to about 95 wt % of the entire resist composition.

The resist composition may further include an organic base (amine quencher) in order to control the exposure amount and to form a resist profile. The organic base may include, e.g., triethylamine, triisobutylamine, trioctylamine, triisodecylamine, triethanolamine, or a mixture thereof. According to an example embodiment, the amount of organic base may range from about 0.1 to about 1 part by weight based on 100 parts by weight of the polymer. Maintaining the amount of the organic base at about 0.1 parts by weight or more may help ensure that the desirable effects thereof are provided. Maintaing the amount of the organic base at about 1 part by weight or less may help ensure that excessive exposure amount is not required, and may help ensure that a pattern is formed.

A process to form a pattern using the resist composition obtained from the above process according to an embodiment will now be described.

A bare silicon wafer or a silicon wafer including an underlayer (such as a silicon oxide layer, a silicon nitride layer, or a silicon nitride oxide layer) on the upper surface may be treated with HMDS (hexamethyldisilazane) or an organic anti-reflection coating (bottom anti-reflective coating, BARC). Thereafter, the resist composition according to an embodiment may be coated on the silicon wafer, e.g., at a thickness of about 100 to about 150 nm, to provide a resist layer.

The silicon wafer formed with the resist layer may be prebaked at a temperature of about 90 to about 120° C. for about 60 to about 90 seconds to remove the solvent, and may be exposed to an exposure light source, e.g., ArF or EUV (extreme UV), E-beam, and so on. In order to drive a chemical reaction in the exposure region of the resist layer, it may be subjected to a PEB (post-exposure bake) at a temperature of about 90 to about 120° C. for about 60 to about 90 seconds. Then, the resist layer may be developed, e.g., in a 2.38 wt % TMAH (tetramethylammonium hydroxide) solution. The exposure region may have a very high solubility to the basic aqueous developing solution, and may be easily dissolved and removed during the development. When the exposure light source used is a ArF excimer laser, an 80 to 100 nm line and space pattern may be obtained at a dose of about 5 to about 50 mJ/cm².

The resist pattern obtained from the above process may be used as a mask, and the underlayer, e.g., a silicon oxide layer, may be etched using an etching gas, e.g., a plasma of halogen gas or a fluorocarbon (CₓF_{y}) gas. The resist pattern that remains on the wafer may be removed, e.g., using a stripper, to provide a desired silicon oxide layer pattern.

The following Examples are provided in order to set forth particular details of one or more embodiments. However, it will be understood that the embodiments are not limited to the particular details described.

### Synthesis Example 1

### Synthesis of Tertiary Adamantyl Alcohol Monomer (2-hydroxy-2-adamantylethyl methacrylate, HAEMA)

A magnesium (Mg, 130 mmol) metal piece and an appropriate amount of tetrahydrofuran (THF) solvent were introduced into a round bottom flask, and a catalytic amount of bromoethane was added thereto to activate the magnesium metal. Then, 2-bromoethyl methacrylate (110 mmol) was slowly added and subjected to reaction at room temperature for 2 hours. A 2-adamantanone (100 mmol) solution was slowly dropped thereto and reacted at a temperature of about 45° C. for 8 hours. After completing the reaction, the reactant was slowly neutralized in an excess diluted hydrochloric acid solution, and 2-hydroxy-2-adamantylethyl methacrylate (HAEMA) was extracted by diethyl ether, then the produced HAEMA was purified through column chromatography (hexane:ethyl acetate=3:1) (yield: 40%).

¹H-NMR (CDCl₃, ppm): 6.1 (s, 1H, vinyl), 5.6 (s, 1H, vinyl), 4.6 (m, 1H, OH), 4.4 (t, 2H, —OCH₂—), 2.1 (t, 2H, —CH₂—), 1.9 (s, 3H, —CH₃), 1.5-2.2 (m, 14H, adamantyl)

### Synthesis Example 2

### Synthesis of Tertiary Norbornyl Alcohol Monomer (2-hydroxy-2-norbornylpropyl methacrylate, HNPMA)

A magnesium metal was activated in accordance with the same method as in Synthesis Example 1, and bromopropyl methacrylate (110 mmol) was slowly added thereto and reacted for about 2 hours.

Then, after a 2-norbornanone (100 mmol) solution was slowly dropped therein to react them, 2-hydroxy-2-norbornylpropyl methacrylate (HNPMA) was purified (yield: 50%) in accordance with the same procedure as in Synthesis Example 1.

### Synthesis Example 3

### Synthesis of Tertiary Adamantyl Alcohol Monomer (2-hydroxy-2-adamantylbutyl methacrylate, HABMA)

A magnesium metal was activated in accordance with the same method as in Synthesis Example 1, and bromobutyl methacrylate (110 mmol) was slowly added thereto and reacted for about 2 hours. Then, after a 2-adamantanone (100 mmol) solution was slowly dropped therein to react them, a product of 2-hydroxy-2-adamantylbutyl methacrylate (HABMA) was purified (yield: 40%) in accordance with the same procedure as in Synthesis Example 1.

### Example 1-1

### Synthesis of Photosensitive Polymer

2-ethyl-2-adamantyl methacrylate (EAMA) (40 mmol), γ-butyrolactonyl methacrylate (GBLMA) (40 mmol), and 2-hydroxy-2-adamantylethyl methacrylate (HAEMA) (20 mmol) synthesized from Synthesis Example 1 were introduced into a round bottom flask and dissolved in a dioxane solvent (four times more than a weight of monomer), and AIBN (azobisisobutyronitrile) (5 mmol) was added thereto and polymerized at a temperature of 80° C. for 6 hours.

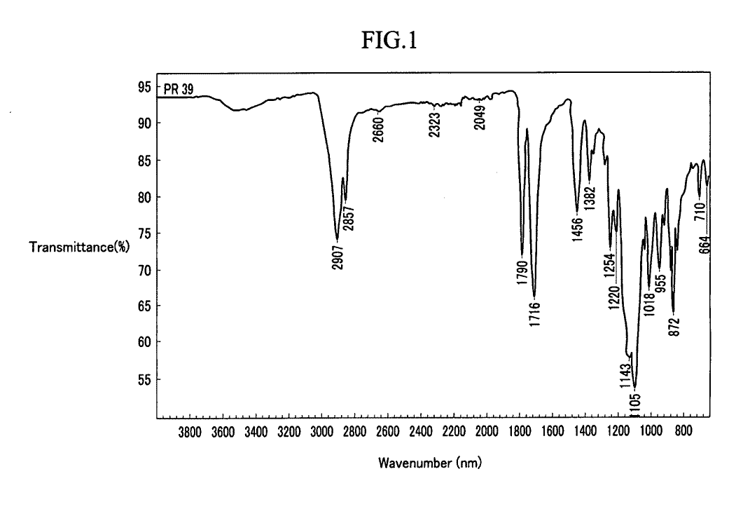

After completing the reaction, the reactant was slowly precipitated in an excess amount of diethyl ether solvent, and the obtained precipitate was filtered. Then, the precipitate was dissolved in an appropriate amount of THF to re-precipitate in diethyl ether. The obtained precipitate was dried in a vacuum oven that was maintained at 50° C. for about 24 hours to recover a polymer (yield: 65%). The obtained polymer is represented by the following Chemical Formula 6, and had a weight average molecular weight (Mw) of 13,800 and a degree of dispersion (Mw/Mn) of 1.8. FIG. 1 shows a FT-IR spectrum of the copolymer synthesized from this example.

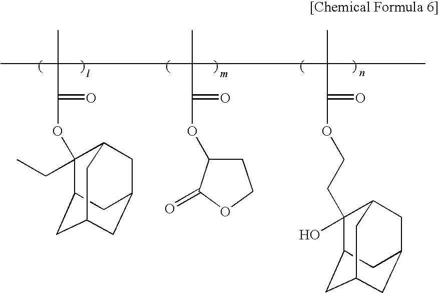

### Example 1-2

### Synthesis of Photosensitive Polymer

A polymer was prepared (yield: 55%) in accordance with the same procedure as in Example 1-1, except that 2-ethyl-2-adamantyl methacrylate (EAMA) (35 mmol), γ-butyrolactonyl methacrylate (GBLMA) (45 mmol) and 2-hydroxy-2-adamantylethyl methacrylate (HAEMA) (20 mmol) synthesized from Synthesis Example 1 were used. The obtained polymer had a weight average molecular weight (Mw) of 12,300 and a degree of dispersion (Mw/Mn) of 1.8.

### Example 1-3

### Synthesis of Photosensitive Polymer

A polymer was prepared (yield: 58%) in accordance with the same procedure as in Example 1-1, except that 2-ethyl-2-adamantyl methacrylate (EAMA) (40 mmol), γ-butyrolactonyl methacrylate (GBLMA) (40 mmol) and 2-hydroxy-2-adamantylethyl methacrylate (HAEMA) (20 mmol) synthesized from Synthesis Example 1 were used. The obtained polymer had a weight average molecular weight (Mw) of 12,700 and a degree of dispersion (Mw/Mn) of 1.8.

### Example 2-1

### Synthesis of Photosensitive Polymer

A polymer represented by the following Chemical Formula 7 was prepared (yield: 60%) in accordance with the same procedure as in Example 1-1, except that 2-methyl-2-adamantyl methacrylate (MAMA) (40 mmol), γ-butyrolactonyl methacrylate (GBLMA) (40 mmol), and 2-hydroxy-2-adamantylethyl methacrylate (HAEMA) (20 mmol) synthesized from Synthesis Example 1 were used. The obtained polymer had a weight average molecular weight (Mw) of 12,100 and a degree of dispersion (Mw/Mn) of 1.8.

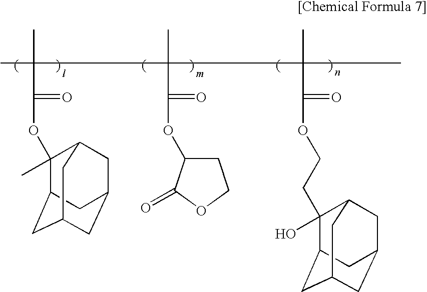

### Example 2-2

### Synthesis of Photosensitive Polymer

2-methyl-2-adamantyl methacrylate (MAMA) (35 mmol), γ-butyrolactonyl methacrylate (GBLMA) (45 mmol), and 2-hydroxy-2-adamantylethyl methacrylate (HAEMA) (20 mmol) synthesized from Synthesis Example 1 were polymerized in accordance with the same procedure as in Example 1 to provide a polymer (yield: 75%). The obtained polymer had a weight average molecular weight (Mw) of 14,800 and a degree of dispersion (Mw/Mn) of 1.8.

### Example 3

### Synthesis of Photosensitive Polymer

2-ethyl-2-adamantyl methacrylate (EAMA) (40 mmol), γ-butyrolactonyl methacrylate (GBLMA) (40 mmol), and 2-hydroxy-2-norbornylpropyl methacrylate (HNPMA) (20 mmol) were introduced into a round bottom flask and dissolved in a dioxane solvent (monomer ×4 times). Then, AIBN (5 mmol) was added thereto and polymerized at 80° C. for 6 hours.

After completing the polymerization, the polymer was recovered in accordance with the same procedure as in Example 1 (yield: 70%). The obtained polymer is represented by the following Chemical Formula 8, and had a weight average molecular weight (Mw) of 14,400 and a degree of dispersion (Mw/Mn) of 1.8.

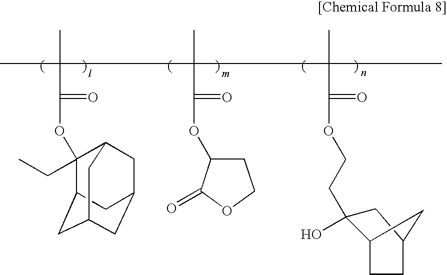

### Example 4

### Synthesis of Photosensitive Polymer

2-methyl-2-adamantyl methacrylate (MAMA) (35 mmol), γ-butyrolactonyl methacrylate (GBLMA) (45 mmol), and 2-hydroxy-2-norbornylpropyl methacrylate (HNPMA) (20 mmol) synthesized from Synthesis Example 2 were polymerized in accordance with the same procedure as in Example 3 to provide a polymer (yield: 60%) that is represented by the following Chemical Formula 9. The obtained polymer had a weight average molecular weight (Mw) of 11,400 and a degree of dispersion (Mw/Mn) of 1.8.

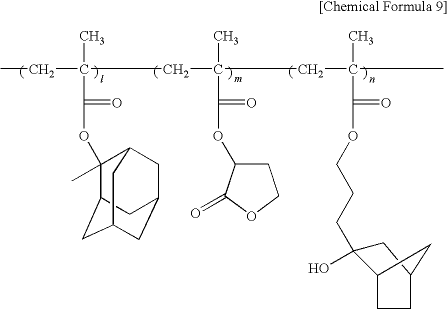

### Example 5

### Synthesis of Photosensitive Polymer

2-ethyl-2-adamantyl methacrylate (EAMA) (40 mmol), γ-butyrolactonyl methacrylate (GBLMA) (40 mmol), and 2-hydroxy-2-adamantylbutyl methacrylate (HABMA) (20 mmol) synthesized from Synthesis Example 3 were polymerized in accordance with the same procedure as in Example 1 to provide a polymer (yield: 70%) that is represented by the following Chemical Formula 10. The obtained polymer had a weight average molecular weight (Mw) of 12,600 and a degree of dispersion (Mw/Mn) of 1.8.

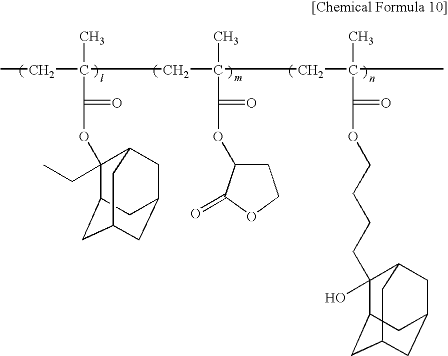

### Example 6

### Synthesis of Photosensitive Polymer

2-methyl-2-adamantyl methacrylate (MAMA) (35 mmol), γ-butyrolactonyl methacrylate (GBLMA) (45 mmol), and 2-hydroxy-2-adamantylbutyl methacrylate (HABMA) (20 mmol) synthesized from Synthesis Example 3 were polymerized in accordance with the same procedure as in Example 1 to provide a polymer (yield: 60%) that is represented by the following Chemical Formula 11. The obtained polymer had a weight average molecular weight (Mw) of 11,600 and a degree of dispersion (Mw/Mn) of 1.8.

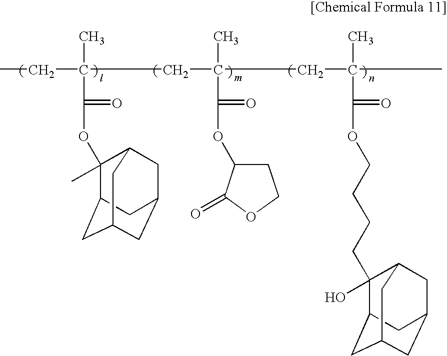

### Example 7

### Preparation of Resist Composition and Lithography Performance

Each polymer (0.8 g) synthesized from Examples 1 to 6 was dissolved in 17 g of PGMEA/EL (6/4) together with 0.03 g of TPS nonaflate (triphenylsulfonium nonaflate) PAG. An organic base of triethanolamine (2 mg) was added thereto and completely dissolved. Then, the resist solution was filtered with a 0.1 μm membrane filter.

The filtered resist solution was coated at a thickness or 120 nm on a silicon wafer to which an organic BARC (AR46, manufactured by Rohm and Haas) was treated in a thickness of 600 Å and pre-baked at 110° C. (soft baking: SB) for 60 seconds, and it was exposed to an ArF scanner (0.78 NA, dipole).

Then, PEB (post-exposure baking) was carried out at 110° C. for 60 seconds, and it was developed in a 2.38 wt % TMAH solution for 60 seconds. The resulting solutions are shown in Table 1.

TABLE 1

| | Polymer Composition | SB | Dose | |
|---|---|---|---|---|
| Composition | (mole ratio) | PEB | (mJ/cm²) | Resolution |
| Example 1-1 | Poly(EAMA-GBLMA-HAEMA) | 110° C./60 sec | 12 | 80 nm |
| | (40:40:20) | 110° C./60 sec | | |
| Example 1-2 | Poly(EAMA-GBLMA-HAEMA) | 110° C./60 sec | 13 | 80 nm |
| | (35:45:20) | 110° C./60 sec | | |
| Example 1-3 | Poly(EAMA-GBLMA-HAEMA) | 100° C./60 sec | 15 | 80 nm |
| | (40:40:20) | 100° C./60 sec | | |
| Example 2-1 | Poly(MAMA-GBLMA-HAEMA) | 110° C./60 sec | 16 | 80 nm |
| | (40:40:20) | 110° C./60 sec | | |
| Example 2-2 | Poly(MAMA-GBLMA-HAEMA) | 110° C./60 sec | 17 | 90 nm |
| | (35:45:20) | | | |
| Example 3 | Poly(EAMA-GBLMA-HNPMA) | 110° C./60 sec | 14 | 80 nm |
| | (40:40:20) | | | |
| Example 4 | Poly(MAMA-GBLMA-HNPMA) | 110° C./60 sec | 15 | 90 nm |
| | (35:45:20) | | | |
| Example 5 | Poly(EAMA:GBLMA:HABMA) | 110° C./60 sec | 16 | 80 nm |
| | (40:40:20) | | | |
| Example 6 | Poly(MAMA:GBLMA:HABMA) | 110° C./60 sec | 14 | 90 nm |
| | (35:45:20) | | | |

As shown in Table 1, a clear line end space (L/S) pattern of 80 to 90 nm was obtained at a dose of 11 to 17 mJ/cm² in all of Examples 1 to 6.

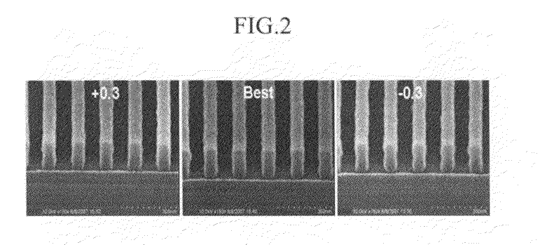

FIG. 2 shows a photograph of patterns formed from a resist solution according to Example 1-1 (photograph taken in a focus of +0.3 and −0.3). As shown in FIG. 2, it was confirmed that the resolution of the pattern was 80 nm and DOF was 600 nm.

As described above, embodiments may provide a copolymer and a resist composition including the same that show excellent performance even in a lithography process that uses an exposure light source emitting light in an ultrashort wavelength region, such as EUV (13.5 nm) as well as the 193 nm ArF region.

A general resist may include an alicyclic group having strong resistance for dry etching, for example an isobornyl group, an adamantyl group, a tricyclodecanyl group, or the like, in the backbone of the copolymer in order to improve dry etching resistance. Such a resist may nonetheless have weak resistance to dry etching because it may have more than a terpolymer structure in order to satisfy solubility requirements in a development solution and adhesion to an underlayer as critical characteristics of a photoresist material, and thereby include a relatively small portion of the alicyclic group. On the other hand, if the terpolymer structure includes a relatively large fraction of the alicyclic compound, it may exhibit reduced adhesion of the resist layer to the underlayer as a result of hydrophobic characteristices of the alicyclic compound. In another general resist, a cycloolefin-maleic anhydride (COMA) alternating polymer may be used as a resist resin. A copolymer such as COMA may exhibit a sharply lower yield, even if it can be prepared with a low cost. In addition, since the COMA polymer includes a hydrophobic alicyclic group as a backbone, it may have bad adhesion to a layer. The COMA type of photosensitive resin also has a problem of storage stability of a resist composition. In contrast, a resist composition according to an embodiment may include a copolymer prepared using an alicyclic compound having a tertiary alcohol group, which may provide both resistance to dry etching and adhesion to an underlayer.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope of the present invention as set forth in the following claims.

What is claimed is:

1. A resist copolymer, comprising:
a repeating unit having the following Chemical Formula 1, a repeating unit having the following Chemical Formula 2, and a repeating unit having the following Chemical Formula 3: 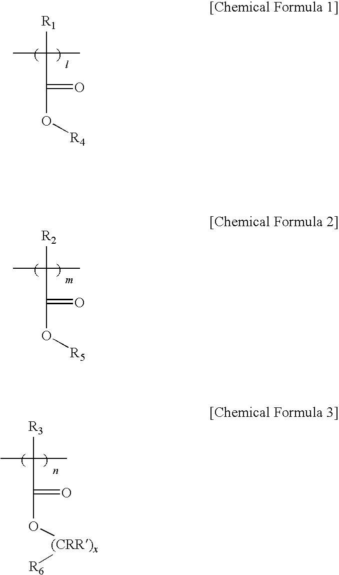
wherein, in the above Chemical Formulae,
R₁ to R₃ are independently hydrogen or a methyl,
R₄ is a C4 to C20 acid-labile group,
R₅ is a lactone-derived group,
R₆ is a tertiary alcohol cycloalkyl,
x is an integer ranging from 1 to 6,
R and R′ are independently hydrogen or an alkyl, and
l, m, and n are mole ratios of the repeating units, l/(l+m+n) being about 0.1 to about 0.5, m/(l+m+n) being about 0.3 to about 0.5, and n/(l+m+n) being about 0.1 to about 0.4.

2. The resist copolymer as claimed in claim 1, wherein the copolymer has a weight average molecular weight (Mw) of about 3,000 to about 30,000.

3. The resist copolymer as claimed in claim 1, wherein the acid-labile group is norbornyl, isobornyl, cyclodecanyl, adamantyl, norbornyl having a lower alkyl substituent, isobornyl having a lower alkyl substituent, cyclodecanyl having a lower alkyl substituent, adamantyl having a lower alkyl substituent, alkoxycarbonyl, alkoxycarbonylalkyl, amyloxycarbonyl, amyloxycarbonylalkyl, 2-tetrahydropyranyloxycarbonylalkyl, 2-tetrahydrofuranyloxycarbonylalkyl, a tertiary alkyl, or an acetal.

4. The resist copolymer as claimed in claim 1, wherein the acid-labile group is 2-methyl-2-norbornyl, 2-ethyl-2-norbornyl, 2-methyl-2-isobornyl, 2-ethyl-2-isobornyl, 8-methyl-8-tricyclodecanyl, 8-ethyl-8-tricyclodecanyl, 2-methyl-2-adamantyl, 2-ethyl-2-adamantyl, 2-propyl-2-adamantyl, t-butoxycarbonyl, t-butoxycarbonylmethyl, t-amyloxycarbonyl, t-amyloxycarbonylmethyl, 1-ethoxyethoxycarbonylmethyl, 2-tetrahydropyranyloxycarbonylalkyl, 2-tetrahydrofuranyloxycarbonylalkyl, t-butyl, triethylcarbyl, 1-methyl cyclohexyl, 1-ethylcyclopentyl, t-amyl, or an acetal.

5. The resist copolymer as claimed in claim 1, wherein:
the lactone-derived group is represented by the following Chemical Formula 4 or 5: 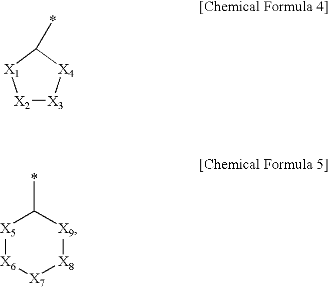
in the above Chemical Formula 4, at least two of X₁ to X₄ are independently CO and O, and the remaining are CR″, where R″ is hydrogen, an alkyl, or an alkylene forming a fused ring with the five-member ring, and
in the above Chemical Formula 5:
at least two of X₅ to X₉ are independently CO and O, and the remaining are CR″, where R″ is hydrogen, an alkyl, or an alkylene forming a fused ring with the five-member ring, or
all X₅ to X₉ are CR′″, where R′″ is hydrogen, an alkyl, or an ester-containing alkylene forming a fused ring with the six-member ring, and at least two of R′″ are linked with each other to form a lactone ring.

6. The resist copolymer as claimed in claim 1, wherein the lactone-derived group is butyrolactonyl, valerolactonyl, 1,3-cyclohexanecarbolactonyl, 2,6-norbornanecarbolacton-5-yl, or 7-oxa-2,6-norbornanecarbolacton-5-yl.

7. The resist copolymer as claimed in claim 1, wherein the tertiary alcohol cycloalkyl is a tertiary alcohol norbornyl, a tertiary alcohol adamantyl, a tertiary alcohol cyclopentanyl, or a tertiary alcohol cyclohexanyl.

8. A resist composition, comprising:
a copolymer including a repeating unit having the following Chemical Formula 1, a repeating unit having the following Chemical Formula 2, and a repeating unit having the following Chemical Formula 3;
a photoacid generator; and
a solvent, 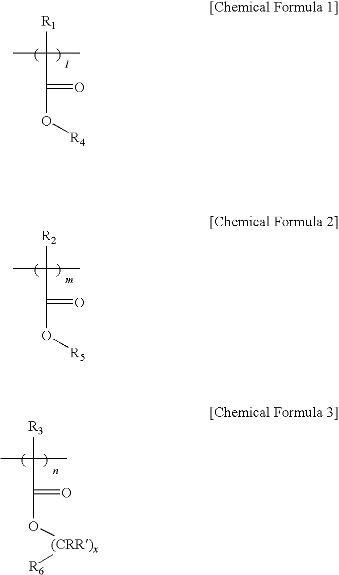
wherein, in the above Chemical Formulae,
R₁ to R₃ are independently hydrogen or methyl,
R₄ is a C4 to C20 acid-labile group,
R₅ is a lactone-derived group,
R₆ is a tertiary alcohol cycloalkyl,
x is an integer ranging from 1 to 6,
R and R′ are independently hydrogen or an alkyl,
l, m, and n are mole ratios of the repeating units, l/(l+m+n) being about 0.1 to about 0.5, m/(l+m+n) being about 0.3 to about 0.5, and n/(l+m+n) being about 0.1 to about 0.4.

9. The resist composition as claimed in claim 8, wherein the copolymer has a weight average molecular weight (Mw) of about 3,000 to about 30,000.

10. The resist composition as claimed in claim 8, wherein the acid-labile group is norbornyl, isobornyl, cyclodecanyl, adamantyl, norbornyl having a lower alkyl substituent, isobornyl having a lower alkyl substituent, cyclodecanyl having a lower alkyl substituent, adamantyl having a lower alkyl substituent, alkoxycarbonyl, alkoxycarbonylalkyl, amyloxycarbonyl, amyloxycarbonylalkyl, 2-tetrahydropyranyloxycarbonylalkyl, 2-tetrahydrofuranyloxycarbonylalkyl, a tertiary alkyl, or an acetal.

11. The resist composition as claimed in claim 8, wherein the acid-labile group is 2-methyl-2-norbornyl, 2-ethyl-2-norbornyl, 2-methyl-2-isobornyl, 2-ethyl-2-isobornyl, 8-methyl-8-tricyclodecanyl, 8-ethyl-8-tricyclodecanyl, 2-methyl-2-adamantyl, 2-ethyl-2-adamantyl, 2-propyl-2-adamantyl, t-butoxycarbonyl, t-butoxycarbonylmethyl, t-amyloxycarbonyl, t-amyloxycarbonylmethyl, 1-ethoxyethoxycarbonylmethyl, 2-tetrahydropyranyloxycarbonylalkyl, 2-tetrahydrofuranyloxycarbonylalkyl, t-butyl, triethylcarbyl, 1-methyl cyclohexyl, 1-ethylcyclopentyl, t-amyl, or an acetal.

12. The resist composition as claimed in claim 8, wherein:
the lactone-derived group is represented by the following Chemical Formula 4 or 5: 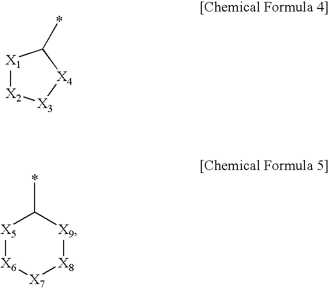
in the above Chemical Formula 4, at least two of X₁ to X₄ are independently CO and O, and the remaining are CR″, where R″ is hydrogen, an alkyl, or an alkylene forming a fused ring with the five-member ring, and
in the above Chemical Formula 5:
at least two of X₅ to X₉ are independently CO and O, and the remaining are CR″, where R″ is hydrogen, an alkyl, or an alkylene forming a fused ring with the five-member ring, or
all of X₅ to X₉ are CR′″, where R′″ is hydrogen, an alkyl, or an ester-containing alkylene forming a fused ring with the six-member ring, and at least two of R′″ are linked each other to form a lactone ring.

13. The resist composition as claimed in claim 8, wherein the lactone-derived group is butyrolactonyl, valerolactonyl, 1,3-cyclohexanecarbolactonyl, 2,6-norbornanecarbolacton-5-yl, or 7-oxa-2,6-norbornanecarbolacton-5-yl.

14. The resist composition as claimed in claim 8, wherein the tertiary alcohol cycloalkyl is a tertiary alcohol norbornyl, a tertiary alcohol adamantyl, a tertiary alcohol cyclopentanyl, or a tertiary alcohol cyclohexanyl.

15. The resist composition as claimed in claim 8, wherein the photoacid generator is included in an amount of about 1 to about 15 parts by weight based on 100 parts by weight of the copolymer.

16. The resist composition as claimed in claim 8, wherein the photoacid generator includes triarylsulfonium salts, diaryliodonium salts, sulfonates, or a mixture thereof.

17. The resist composition as claimed in claim 8, wherein the photoacid generator includes triarylsulfonium triflate, diaryliodonium triflate, triarylsulfonium nonaflate, diaryliodonium nonaflate, succinimidyl triflate, 2,6-dinitrobenzyl sulfonate, or a mixture thereof.

18. The resist composition as claimed in claim 8, wherein the composition further comprises about 0.1 to about 1.0 parts by weight of an organic base based on 100 parts by weight of the copolymer.

19. The resist composition as claimed in claim 18, wherein the organic base is triethylamine, triisobutylamine, trioctylamine, triisodecylamine, triethanolamine, or a mixture thereof.
